(19) United States
(12) Patent Application Publication
(10) Pub. No.: US 2026/0006905 A1
(43) Pub. Date: Jan. 1, 2026

(54) SEMICONDUCTOR DEVICE AND METHOD OF MANUFACTURING THE SAME

(71) Applicant: Renesas Electronics Corporation, Tokyo (JP)

(72) Inventors: Takuto WATANABE, Tokyo (JP); Takahiro MORI, Tokyo (JP)

(21) Appl. No.: 19/241,957

(22) Filed: Jun. 18, 2025

(30) Foreign Application Priority Data
Jul. 1, 2024 (JP) 2024-105968

(51) Int. Cl. H10D 84/83; H10D 62/10; H10D 84/01

(52) U.S. Cl. CPC H10D 84/835; H10D 62/109; H10D 84/013; H10D 84/0151; H10D 84/0156

(57) ABSTRACT

An n-type source region and an n-type drain region ND1 are formed in a semiconductor substrate. A gate electrode is formed via a gate insulating film on a portion of the semiconductor substrate located between the source region and the drain region. A p-type impurity region is: formed in a portion of the semiconductor substrate located under the drain region, under the gate electrode, and under the source region. An impurity concentration of the impurity region is higher than an impurity concentration of the semiconductor substrate. The impurity region is spaced apart from an upper surface of the semiconductor substrate.

### CROSS-REFERENCE TO RELATED APPLICATIONS

The disclosure of Japanese Patent Application No. 2024-105968 filed on Jul. 1, 2024, including the specification, drawings and abstract is incorporated herein by reference in its entirety.

### BACKGROUND

The present invention relates to a semiconductor device and a method of manufacturing the same.

As a type of MISFET (Metal Insulator Semiconductor Field Effect Transistor), LDMOS (Laterally Metal Oxide Semiconductor) is known. LDMOS has a low-concentration drift region arranged between a high-concentration drain region and a gate electrode in plan view.

There are disclosed techniques listed below.
[Patent Document 1] Japanese Unexamined Patent Application Publication No. 2017-152559

For example, Patent Document 1 discloses a semiconductor device including LDMOS, where a p-type semiconductor region is formed under the gate electrode to improve the breakdown voltage of the LDMOS. Additionally, to electrically isolate the LDMOS from other semiconductor elements, deep isolation regions are formed in the interlayer insulating film and the semiconductor substrate.

### SUMMARY

In semiconductor devices, various MISFETs are formed in addition to LDMOS, depending on the circuit applications. As various MISFETs, for example, an n-type MISFET with a p-type well region formed in the semiconductor substrate and an n-type MISFET without a p-type well region is used. The n-type MISFET without a p-type well region uses a p-type semiconductor substrate with a relatively low impurity concentration as the channel region. Therefore, in the n-type MISFET without a p-type well region, punch-through is more likely to occur compared to the n-type MISFET with a p-type well region, and leakage current is more likely to occur during off-operation, and the breakdown voltage during off-operation is more likely to decrease. Consequently, there is a risk of reduced reliability of semiconductor devices.

To suppress the occurrence of punch-through, it is conceivable to increase the gate length of the gate electrode, but this increases the planar area of the MISFET, making the size of the semiconductor device larger. Moreover, it becomes difficult to shrink the MISFET, making it difficult to miniaturize the semiconductor device.

Other problems and novel features will become apparent from the description of this specification and the accompanying drawings.

In one embodiment, a semiconductor device includes a semiconductor substrate of a first conductivity type, a first source region of a second conductivity type formed in the semiconductor substrate, a first drain region of the second conductivity type formed in the semiconductor substrate, and a first gate electrode formed via a first gate insulating film on a portion of the semiconductor substrate located between the first source region and the first drain region. A first impurity region of the first conductivity type is formed in a portion of the semiconductor substrate located under the first drain region, under the first gate electrode, and under the first source region. The first impurity region is spaced apart from the upper surface of the semiconductor substrate. The impurity concentration of the first impurity region is higher than the impurity concentration of the semiconductor substrate. No impurity region of the first conductivity type other than the semiconductor substrate and the first impurity region is formed in a portion of the semiconductor substrate located between the first drain region, the first gate electrode, and the first source region, and the first impurity region.

In one embodiment, a method of manufacturing a semiconductor device includes preparing a semiconductor substrate of a first conductivity type, forming a first impurity region of the first conductivity type in the semiconductor substrate, forming a first gate insulating film on the upper surface of the semiconductor substrate, forming a first gate electrode on the first gate insulating film, and forming a first source region of a second conductivity type and a first drain region of the second conductivity type in the semiconductor substrate. The first impurity region is formed in a portion of the semiconductor substrate located under the first drain region, under the first gate electrode, and under the first source region. The first impurity region is spaced apart from the upper surface of the semiconductor substrate. The impurity concentration of the first impurity region is higher than the impurity concentration of the semiconductor substrate. No impurity region of the first conductivity type other than the semiconductor substrate and the first impurity region is formed in a portion of the semiconductor substrate located between the first drain region, the first gate electrode, and the first source region, and the first impurity region.

According to one embodiment, the reliability of the semiconductor device can be improved.

### BRIEF DESCRIPTION OF THE DRAWINGS

FIG. 1 is a cross-sectional view showing a semiconductor device in a first embodiment.

FIG. 2 is a diagram showing the potential distribution by simulation in a first examined example.

FIG. 3 is a diagram showing the potential distribution by simulation in the first embodiment.

FIG. 4 is a diagram showing the potential distribution by simulation in a second examined example.

FIG. 5 is a diagram showing the potential distribution by simulation in a third examined example.

FIG. 6 is a graph showing simulation results.

FIG. 7 is a graph showing simulation results.

FIG. 8 is a graph showing the impurity concentration profile of the impurity region in the first embodiment.

FIG. 9 is a diagram showing the potential distribution by simulation in the first embodiment.

FIG. 10 is a cross-sectional view showing a manufacturing step of the semiconductor device in the first embodiment.

FIG. 11 is a cross-sectional view showing a manufacturing step of the semiconductor device following FIG. 10.

FIG. 12 is a cross-sectional view showing a manufacturing step of the semiconductor device following FIG. 11.

FIG. 13 is a cross-sectional view showing a manufacturing step of the semiconductor device following FIG. 12.

FIG. 14 is a cross-sectional view showing a manufacturing step of the semiconductor device following FIG. 13.

FIG. 15 is a cross-sectional view showing a manufacturing step of the semiconductor device following FIG. 14.

FIG. 16 is a cross-sectional view showing a manufacturing step of the semiconductor device following FIG. 15.

FIG. 17 is a cross-sectional view showing a manufacturing step of the semiconductor device following FIG. 16.

FIG. 18 is a cross-sectional view showing a semiconductor device in a second embodiment.

FIG. 19 is a plan view showing a semiconductor device in the second embodiment.

FIG. 20 is a graph showing simulation results in the second embodiment.

FIG. 21 is a diagram showing the potential distribution by simulation in a fourth examined example.

FIG. 22 is a diagram showing the potential distribution by simulation in the second embodiment.

FIG. 23 is a diagram showing the potential distribution by simulation in a fifth examined example.

FIG. 24 is a diagram showing the potential distribution by simulation in a sixth examined example.

FIG. 25 is a graph showing simulation results.

FIG. 26 is a graph showing simulation results.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In this context, the X direction, Y direction, and Z direction described in this application intersect each other and are orthogonal to each other. In this application, the Z direction is the vertical direction, depth direction, or thickness direction of a structure. Also, expressions such as “plan view” or “plan perspective” used in this application mean viewing the plane constituted by the X direction and Y direction from the Z direction.

### First Embodiment

### Structure of Semiconductor Device

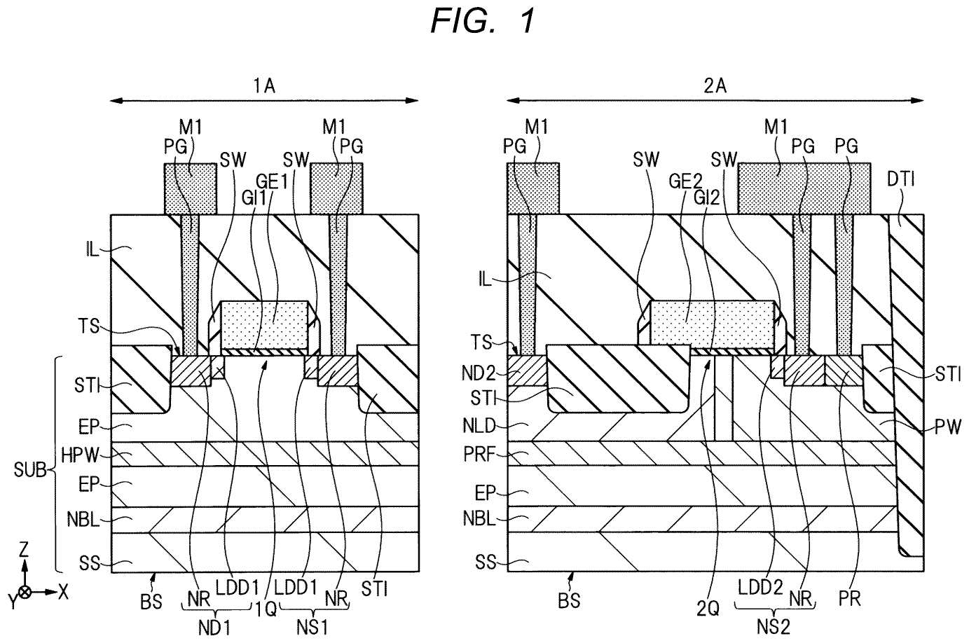

The semiconductor device in the first embodiment will be described below with reference to FIG. 1. The semiconductor device includes a region 1A having a MISFET 1Q and a region 2A having a MISFET 2Q as LDMOS.

As shown in FIG. 1, the semiconductor device includes a p-type semiconductor substrate SUB having an upper surface TS and a lower surface BS, an n-type buried region (impurity region) NBL, and an element isolation portion STI. In the first embodiment, the semiconductor substrate SUB includes, for example, a supporting substrate SS and a semiconductor layer EP formed on the supporting substrate SS. The supporting substrate SS is, for example, a p-type silicon substrate. The semiconductor layer EP is, for example, a p-type silicon layer. The n-type buried region NBL is formed in the semiconductor substrate SUB. In the following description, various impurity regions formed in the semiconductor substrate SUB may specifically be formed in the semiconductor layer EP. Note that the semiconductor substrate SUB may be a single-layer p-type silicon substrate.

In the semiconductor substrate SUB, the element isolation portion STI is formed to reach a predetermined depth from the upper surface TS of the semiconductor substrate SUB. The element isolation portion STI includes a trench formed in the semiconductor substrate SUB and an insulating film embedded inside the trench. The insulation film is, for example, a silicon oxide film. The depth of the element isolation portion STI is, for example, 0.2 μm or more and 0.5 μm or less.

### Structure of MISFET 1Q in Region 1A

The MISFET 10 includes an n-type source region NS1, an n-type drain region ND1, a gate insulating film GI1, a gate electrode GE1, a sidewall spacer SW, the semiconductor layer EP, and a p-type impurity region HPW.

In the region 1A, the source region NS1 and the drain region ND1 are formed in the semiconductor substrate SUB to reach a predetermined depth from the upper surface TS of the semiconductor substrate SUB. The depth of the source region NS1 and the depth of the drain region ND1 are shallower than the depth of the element isolation portion STI. The source region NS1 and the drain region ND1 each include an n-type low-concentration diffusion region (impurity region) LDD1 and an n-type high-concentration diffusion region (impurity region) NR. The impurity concentration of the high-concentration diffusion region NR is higher than the impurity concentration of the low-concentration diffusion region LDD1.

In the region 1A, the gate insulating film GI1 is formed on the upper surface TS of the semiconductor substrate SUB. The gate insulating film GI1 is made of, for example, a silicon oxide film. The gate electrode GE1 is formed on the gate insulating film GI1. The gate electrode GE1 is made of, for example, an n-type polycrystalline silicon film. The sidewall spacer SW is formed on a side surface of the gate electrode GE1. The sidewall spacer SW includes, for example, a silicon oxide film and a silicon nitride film formed on the silicon oxide film.

The gate electrode GE1 is formed via the gate insulating film GI1 on a portion of the semiconductor substrate SUB located between the source region NS1 and the drain region ND1. The portion of the semiconductor substrate SUB (semiconductor layer EP) located between the source region NS1 and the drain region ND1, and under the gate electrode GE1, functions as the channel region of the MISFET 1Q.

The impurity region HPW is formed in the semiconductor substrate SUB and is located over the buried region NBL. The impurity concentration of the impurity region HPW is higher than the impurity concentration of the semiconductor substrate SUB (semiconductor layer EP).

The impurity region HPW is formed in the portion of the semiconductor substrate SUB located under the drain region ND1, under the gate electrode GE1, and under the source region NS1. Additionally, the impurity region HPW is spaced apart from the upper surface TS of the semiconductor substrate SUB and the buried region NBL. Furthermore, in the portion of the semiconductor substrate SUB located between the drain region ND1, the gate electrode GE1, and the source region NS1, no p-type impurity region other than the semiconductor substrate SUB and the impurity region HPW is formed.

In other words, the impurity concentration at the location over the impurity region HPW in the semiconductor substrate SUB is the same as the impurity concentration at the location under the impurity region HPW in the semiconductor substrate SUB.

The main feature of the first embodiment is that the MISFET 1Q has the impurity region HPW, which will be described in detail later.

### Structure of MISFET 2Q in Region 2A

The MISFET 20 includes a gate insulating film GI2, a gate electrode GE2, the sidewall spacer SW, an n-type drift region (impurity region) NLD, a p-type well region (impurity region) PW, an n-type source region NS2, an n-type drain region ND2, a high-concentration diffusion region (impurity region) PR, and a p-type resurf region PRF.

In the region 2A, the drift region NLD and the well region PW are formed in the semiconductor substrate SUB to reach a predetermined depth from the upper surface TS of the semiconductor substrate SUB and are located over the buried region NBL. The depth of the drift region NLD and the depth of the well region PW are deeper than the depth of the element isolation portion STI. The impurity concentration of the well region PW is higher than the impurity concentration of the semiconductor layer EP.

In the well region PW, the source region NS2 and the high-concentration diffusion region PR are formed. The source region NS2 includes an n-type low-concentration diffusion region (impurity region) LDD2 and the n-type high-concentration diffusion region NR formed in the semiconductor substrate SUB.

In the drift region NLD, the drain region (impurity region) ND2 is formed. The impurity concentration of the drain region ND2, the impurity concentration of the low-concentration diffusion region LDD2, and the impurity concentration of the high-concentration diffusion region NR are higher than the impurity concentration of the drift region NLD. The impurity concentration of the high-concentration diffusion region NR is higher than the impurity concentration of the low-concentration diffusion region LDD2. The impurity concentration of the high-concentration diffusion region PR is higher than the impurity concentration of the well region PW.

In the region 2A, the gate insulating film GI2 is formed on the upper surface TS of the semiconductor substrate SUB. The gate insulation film GI2 is made of, for example, a silicon oxide film. Additionally, the element isolation portion STI is formed in the drift region NLD. The gate electrode GE2 is formed on the gate insulating film GI2 and on a part of the element isolation portion STI located in the drift region NLD. The gate electrode GE2 is made of, for example, an n-type polycrystalline silicon film. The sidewall spacer SW is formed on a side surface of the gate electrode GE2.

The portion of the semiconductor substrate SUB (semiconductor layer EP, well region PW) located between the source region NS1 and the drift region NLD, and under the gate electrode GE2, functions as the channel region of the MISFET 2Q.

The resurf region (impurity region) PRF is formed in the semiconductor substrate SUB. The resurf region PRF is located over the buried region NBL and is formed in the portion of the semiconductor substrate SUB located under the drift region NLD and under the well region PW. The impurity concentration of the resurf region PRF is higher than the impurity concentration of the semiconductor substrate SUB (semiconductor layer EP).

As will be described later, the step of forming the resurf region PRF and the step of forming the impurity region HPW are performed as the same step. Therefore, the impurity profile of the resurf region PRF is the same as the impurity profile of the impurity region HPW.

The semiconductor device includes an interlayer insulating film IL, a plurality of plugs PG, a plurality of wirings M1, and an element isolation portion DTI. In the region 1A and the region 2A, the interlayer insulating film IL is formed on the upper surface TS of the semiconductor substrate SUB to cover the MISFET 1Q and the MISFET 2Q. The interlayer insulating film IL is made of, for example, a silicon oxide film. A plurality of holes are formed in the interlayer insulating film IL. Inside each of the plurality of holes, the plug PG is formed. Each of the plurality of plugs PG includes, for example, a barrier metal film and a conductive film formed on the barrier metal film. The barrier metal film includes, for example, a titanium film and a titanium nitride film, and the conductive film is, for example, a tungsten film. Although not shown here, the plug PG connected to the gate electrode GE1 or the gate electrode GE2 is also formed in the interlayer insulating film IL.

The plurality of wirings M1 are formed on the interlayer insulating film IL. Each of the plurality of wirings M1 is electrically connected to the drain region ND1, the source region NS1, the drain region ND2, the source region NS2, the high-concentration diffusion region PR, the gate electrode GE1, or the gate electrode GE2 via the plug PG.

Each of the plurality of wirings M1 includes a lower barrier metal film, a conductive film formed on the lower barrier metal film, and an upper barrier metal film formed on the conductive film. The lower barrier metal film includes a titanium film, and a titanium nitride film formed on the titanium film. The conductive film includes an aluminum alloy film with copper or silicon added to an aluminum film. The upper barrier metal film includes a titanium nitride film.

Additionally, in the region 2A, the element isolation portion DTI is formed in the semiconductor substrate SUB to reach a predetermined depth from the upper surface TS of the semiconductor substrate SUB. The element isolation portion DTI is also formed in the interlayer insulating film IL and penetrates through the interlayer insulating film IL. The element isolation portion DTI includes a trench formed in the interlayer insulating film IL and the semiconductor substrate SUB, and an insulating film embedded in the trench. The insulation film is, for example, a silicon oxide film.

The depth of the element isolation portion DTI is deeper than the depth of the element isolation portion STI. Additionally, the element isolation portion DTI is in contact with the resurf region PRF and the buried region NBL. The element isolation portion DTI electrically isolates the MISFET 2Q from other semiconductor elements such as the MISFET 1Q.

### Comparison Between Examined Example and First Embodiment

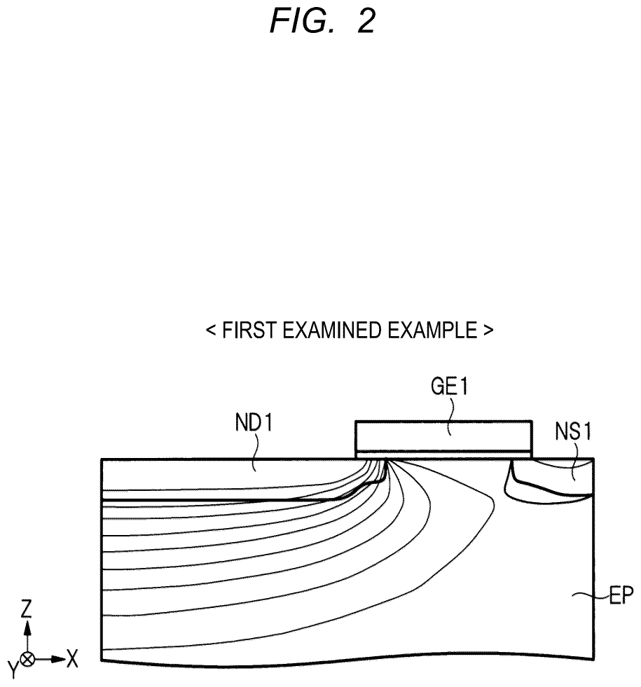

The effect of the impurity region HPW included in the MISFET 1Q will be described below using FIGS. 2 to 7. FIGS. 2 to 5 show the potential distribution obtained by simulations conducted by the inventors of the present application to examine the occurrence of leakage current (Ioff characteristics) during the off operation of the MISFET 1Q. Here, the voltage Vg applied to the gate electrode GE1 is set to −1V, the voltage Vd applied to the drain region ND1 is set to 3.3V, and the voltage Vs applied to the source region NS1 and the voltage Vb applied to the semiconductor layer EP are set to 0V as an example.

As shown in FIG. 2, in the first examined example, unlike the first embodiment, the impurity region HPW is not formed. Also, in the semiconductor layer EP, no impurity region with a higher impurity concentration than the semiconductor layer EP, such as the well region PW, is formed. Therefore, in the first examined example, equipotential lines extending from the drain region ND1 easily reach the source region NS1, making punch-through likely to occur. Consequently, leakage current is likely to occur in the MISFET 1Q, which may reduce the reliability of the semiconductor device.

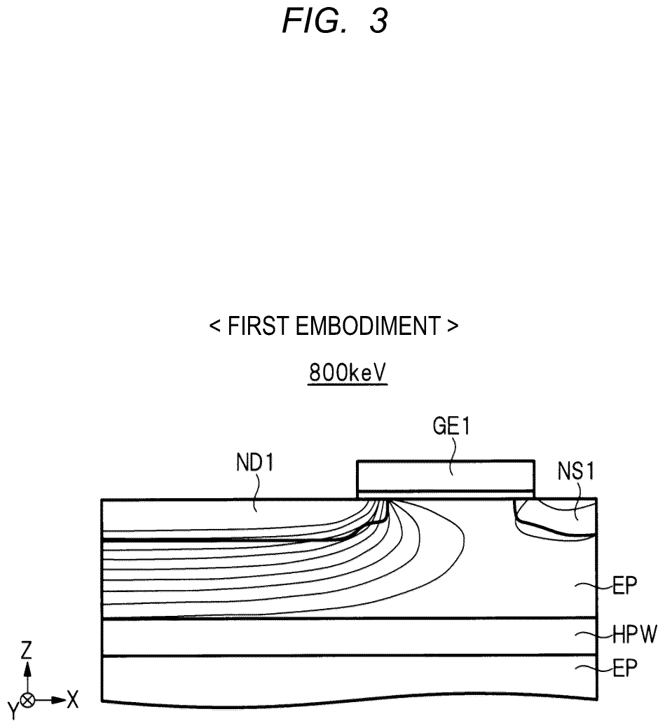

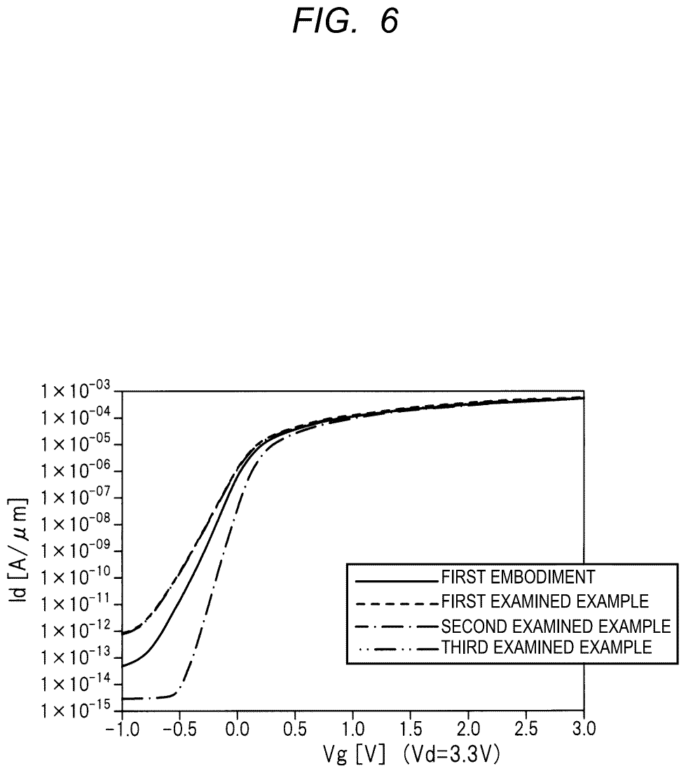

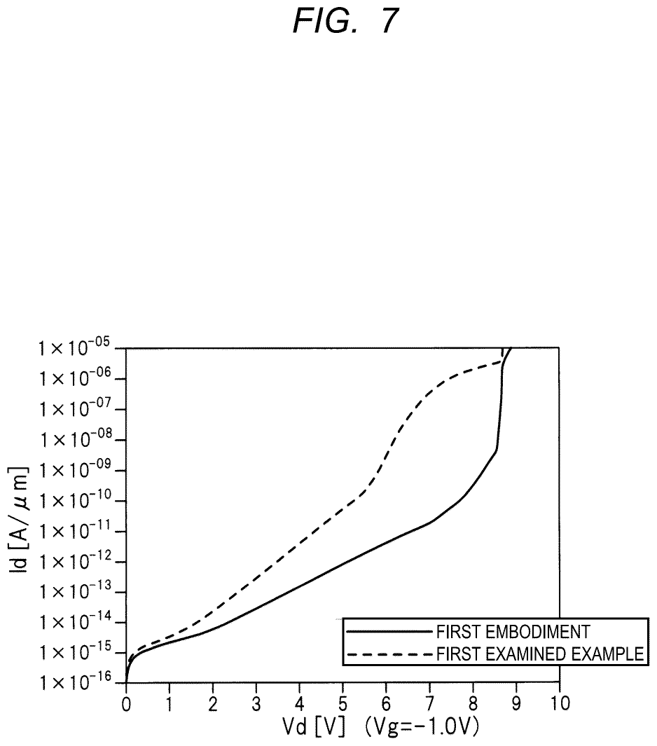

As shown in FIG. 3, in the first embodiment, the impurity region HPW is formed, preventing equipotential lines from reaching the source region NS1. Therefore, as shown in FIG. 6, punch-through is less likely to occur. Additionally, as shown in FIG. 7, in the first embodiment, compared to the first examined example, the occurrence of leakage current during the off operation can be suppressed, and the breakdown voltage of the MISFET 1Q during the off operation can be improved. Therefore, the reliability of the semiconductor device can be improved.

Furthermore, in the first embodiment, since punch-through is less likely to occur, it is easier to shrink the MISFET 1Q, making it easier to miniaturize the semiconductor device. Additionally, the impurity region HPW can be formed in the same step as the step of forming the resurf region PRF. Therefore, the increase in manufacturing costs can be suppressed.

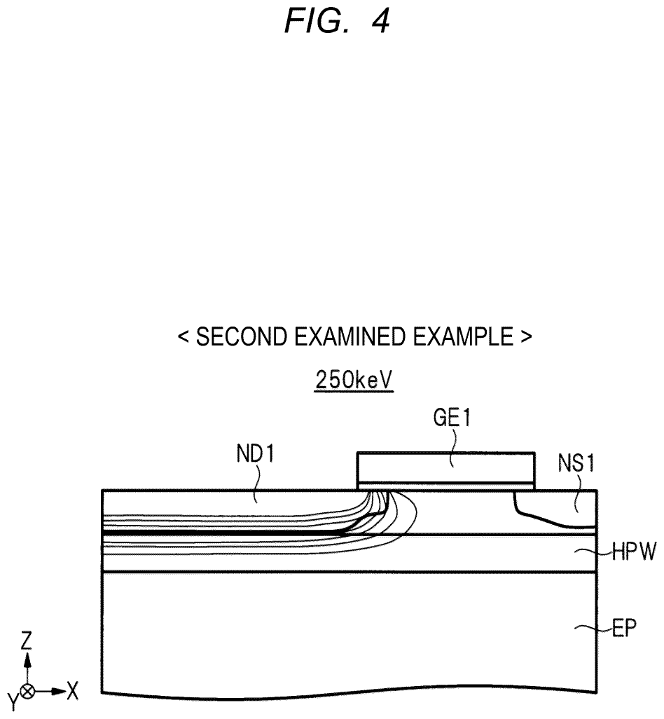

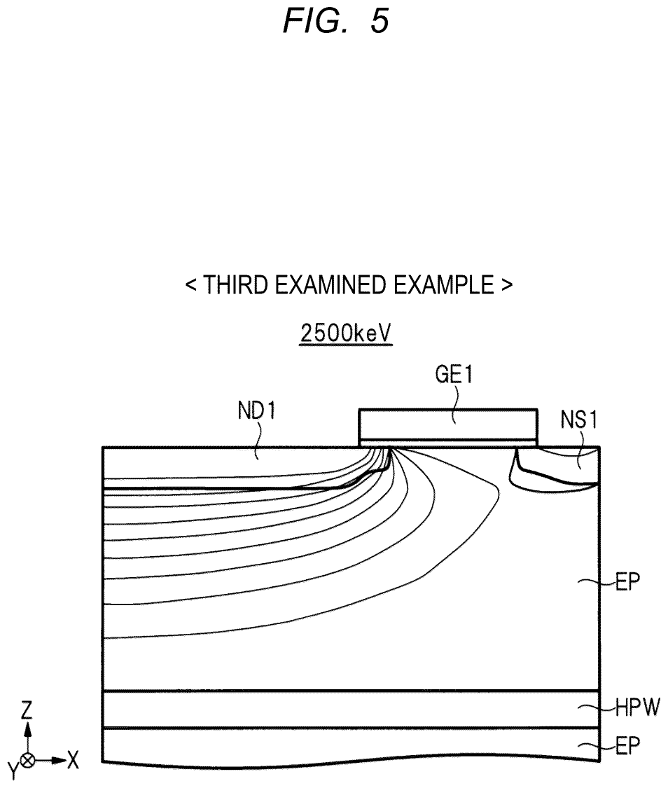

As shown in FIGS. 4 and 5, in the second examined example and the third examined example, the impurity region HPW is formed. However, the position where the impurity region HPW is formed in the second examined example and the third examined example differs from the position where the impurity region HPW is formed in the first embodiment. In the ion implantation step for forming the impurity region HPW, boron (B) is used. Additionally, the ion implantation energy is 800 keV in the first embodiment, 250 keV in the second examined example, and 2500 keV in the third examined example.

As shown in FIG. 4, since the position of the impurity region HPW in the second examined example is shallower than the position of the impurity region HPW in the first embodiment, the impurities contained in the impurity region HPW diffuse into the channel region of the MISFET 1Q. Therefore, in the second examined example, while the occurrence of punch-through can be suppressed, the characteristics of the MISFET 1Q fluctuate significantly compared to the first embodiment. For example, as shown in FIG. 6, in the second examined example, the threshold voltage of the MISFET 1Q becomes higher compared to the first embodiment, and the driving timing of the MISFET 1Q is delayed.

As shown in FIG. 5, since the position of the impurity region HPW in the third examined example is deeper than the position of the impurity region HPW in the first embodiment, the extension of the equipotential lines cannot be suppressed. Therefore, in the third examined example, the occurrence of punch-through cannot be suppressed, and as shown in FIG. 6, the characteristics of the third examined example become almost the same as those of the first examined example. In other words, if the position of the impurity region HPW is too deep, the effect of the impurity region HPW cannot be exerted.

If the impurity region HPW is somewhat distant from the upper surface TS of the semiconductor substrate SUB, the impurity region HPW hardly affects the characteristic variation of the MISFET 1Q and can suppress the occurrence of punch-through. To further enhance the effect of suppressing the occurrence of punch-through, the following lower and upper limit conditions may be set.

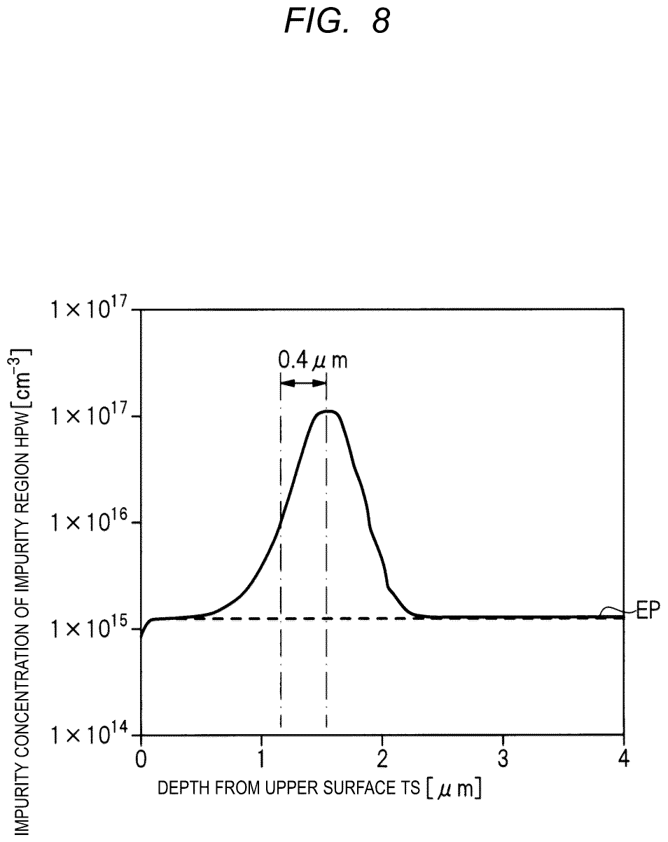

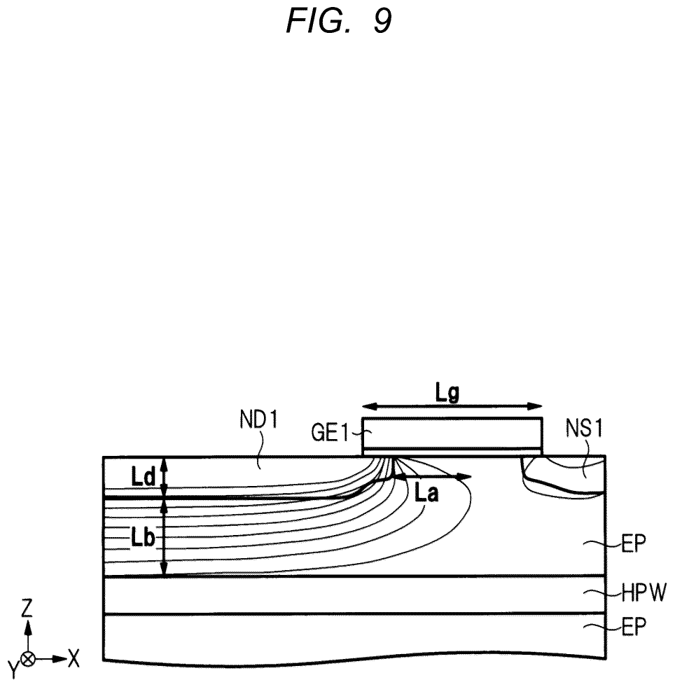

Below, the position of the impurity concentration peak of the impurity region HPW will be described using FIGS. 8 and 9. The lower limit condition of the position of the impurity concentration peak of the impurity region HPW will be described using FIG. 8, and the upper limit condition will be described using FIG. 9.

As shown in FIG. 8, the impurity profile of the impurity region HPW has a half-width of about 0.4 μm from the position of the impurity concentration peak of the impurity region HPW. As explained in the second examined example in FIG. 4, if the position of the impurity region HPW is too shallow, there is a problem that the characteristics of the MISFET 1Q fluctuate significantly. If the impurity concentration peak of the impurity region HPW is located at a position more than the above half-width from the upper surface TS of the semiconductor substrate SUB, the impurity region HPW hardly affects the characteristic variation of the MISFET 1Q. Therefore, it is preferable that the impurity concentration peak of the impurity region HPW is located at a position 0.4 μm or more from the upper surface TS of the semiconductor substrate SUB.

Also, since the half-width of the impurity region HPW is approximately the same as the depth of the element isolation portion STI, it can be said that the impurity concentration peak of the impurity region HPW is located at a position deeper than the depth of the element isolation portion STI.

The gate length Lg shown in FIG. 9 is the length of the gate electrode GE1 in the direction (X direction) from the drain region ND1 to the source region NS1. The distance Ld is the depth of the drain region ND1. The distance La is the spread of the equipotential line extending in the X direction from the drain region ND1. The distance Lb is the spread of the equipotential line extending in the Z direction from the drain region ND1.

The distance Lb is about half of the distance La. When punch-through occurs, the distance La becomes almost the same as the gate length Lg. Therefore, as a condition for preventing punch-through, it is preferable that the impurity concentration peak of the impurity region HPW is located at a position shallower than the sum of the depth Ld of the drain region ND1 and twice the gate length Lg from the upper surface TS of the semiconductor substrate SUB.

In the first embodiment, the distance Ld is, for example, 0.3 μm, and the gate length Lg is, for example, 1.0 μm. Therefore, it is preferable that the impurity concentration peak of the impurity region HPW is located at a position 2.3 μm or less from the upper surface TS of the semiconductor substrate SUB.

By setting the position of the impurity concentration peak of the impurity region HPW as described above, in the MISFET 1Q, the occurrence of leakage current during off-operation can be suppressed, the breakdown voltage during off-operation can be improved, and the characteristic variation of the MISFET 1Q can be suppressed.

### Manufacturing Method of Semiconductor Device

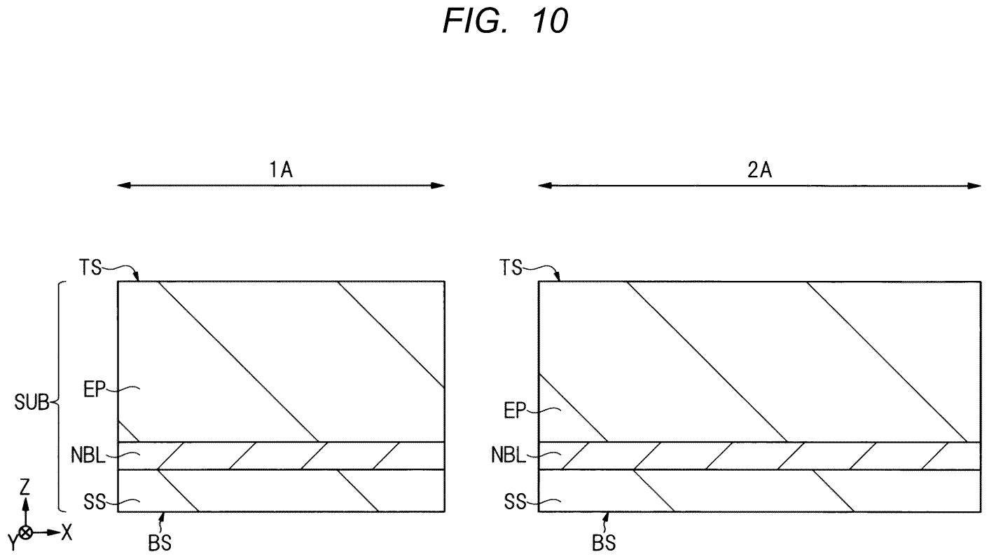

Below, each manufacturing step included in the manufacturing method of the semiconductor device in the first embodiment will be described using FIGS. 10 to 17.

As shown in FIG. 10, the semiconductor substrate SUB is prepared. As described above, the semiconductor substrate SUB may be a single-layer p-type silicon substrate, but in the first embodiment, the semiconductor substrate SUB includes the supporting substrate SS and the semiconductor layer EP. First, the supporting substrate SS made of p-type silicon is prepared. Next, by epitaxial growth, the semiconductor layer EP, which is a p-type silicon layer, is formed on the supporting substrate SS.

Next, by photolithography and ion implantation, the buried region NBL is formed in the semiconductor substrate SUB. Note that after forming the buried region NBL in the supporting substrate SS, the semiconductor layer EP may be formed on the supporting substrate SS.

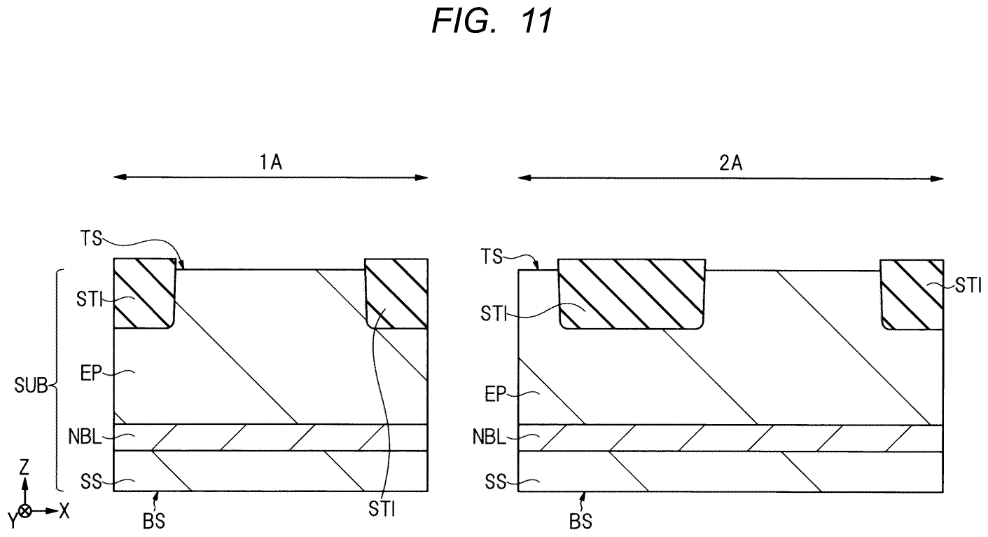

As shown in FIG. 11, the element isolation portion STI is formed in the semiconductor substrate SUB to reach a predetermined depth from the upper surface TS of the semiconductor substrate SUB.

First, on the upper surface TS of the semiconductor substrate SUB, for example, by a film-forming process using the CVD method, a silicon nitride film is formed. Next, by patterning the silicon nitride film, a hard mask is formed. Next, by performing anisotropic etching using the hard mask as a mask, a trench is formed in the semiconductor substrate SUB.

Next, to fill the inside of the trench, an insulating film such as a silicon oxide film is formed on the upper surface TS of the semiconductor substrate SUB. Next, by a polishing process using the CMP method, the insulating film located outside the trench is removed so that the insulating film remains inside the trench. In this way, the element isolation portion STI including the trench and the insulating film is formed. Thereafter, for example, by isotropic etching, the hard mask is selectively removed to expose the upper surface TS of the semiconductor substrate SUB.

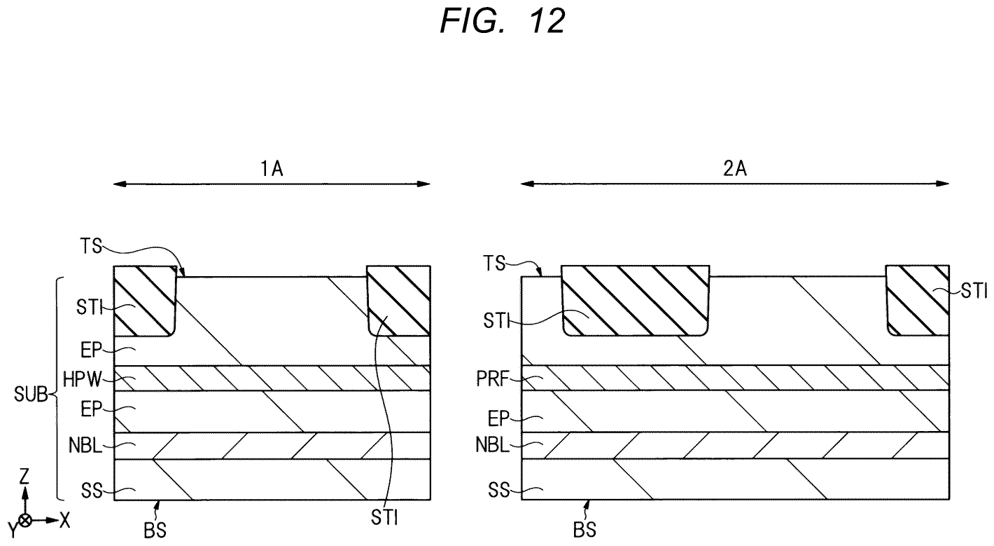

As shown in FIG. 12, by photolithography and ion implantation, the impurity region HPW is formed in the semiconductor substrate SUB in the region 1A, and the resurf region PRF is formed in the semiconductor substrate SUB in the region 2A. Note that the impurity region HPW and the resurf region PRF are formed by the same ion implantation step, and as described in FIG. 3, boron (B) is used in this ion implantation step, and the dose amount is, for example, 2.0×10¹¹ cm⁻² or more and 1.0×10¹³ cm⁻² or less. Also, it is preferable that the ion implantation energy is 500 keV or more and 1200 keV or less, and more preferably 800 keV.

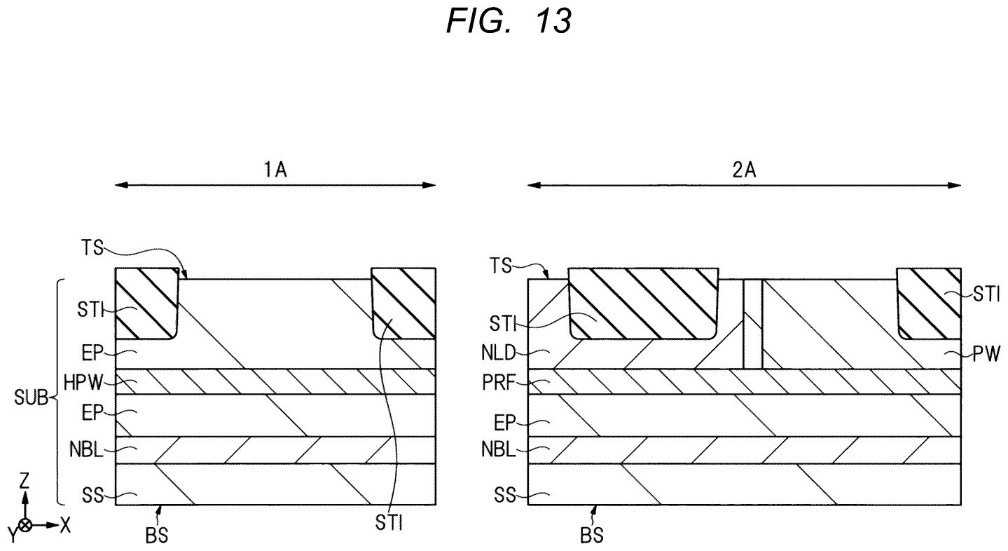

As shown in FIG. 13, by photolithography and ion implantation, the drift region NLD and the well region PW are sequentially formed in the semiconductor substrate SUB in the region 2A. The drift region NLD and the well region PW are each formed to reach a predetermined depth from the upper surface TS of the semiconductor substrate SUB.

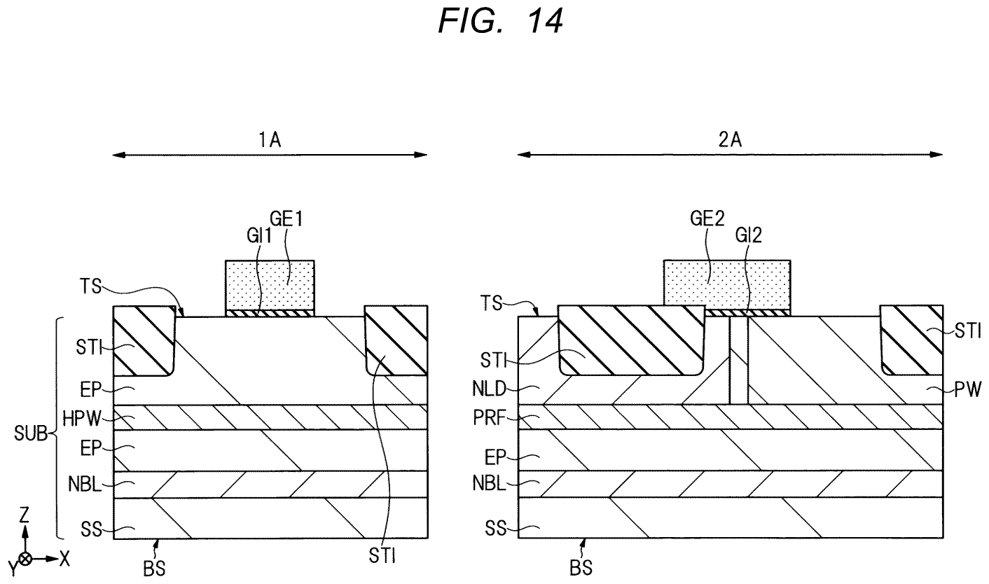

As shown in FIG. 14, the gate insulating film GI1 and the gate insulating film GI2 are formed on the upper surface TS of the semiconductor substrate SUB. Next, the gate electrode GE1 is formed on the gate insulating film GI1, and the gate electrode GE2 is formed on the gate insulating film GI2.

First, for example, by thermal oxidation, the gate insulating film GI1 is formed on the upper surface TS of the semiconductor substrate SUB in the region 1A, and the gate insulating film GI2 is formed on the drift region NLD and the well region PW in the region 2A. Next, by a film-forming process using the CVD method, a conductive film is formed on the gate insulating film GI1, the gate insulating film GI2, and the element isolation portion STI. The conductive film is, for example, a polycrystalline silicon film into which n-type impurities are introduced.

Next, by patterning the conductive film, the gate electrode GE1 made of the conductive film is formed on the gate insulating film GI1 in the region 1A, and the gate electrode GE2 made of the conductive film is formed on the gate insulating film GI2 and a part of the element isolation portion STI in the region 2A. Thereafter, by isotropic etching, the gate insulation film GI1 and the gate insulating film GI2 exposed from the gate electrode GE1 and the gate electrode GE2 are removed.

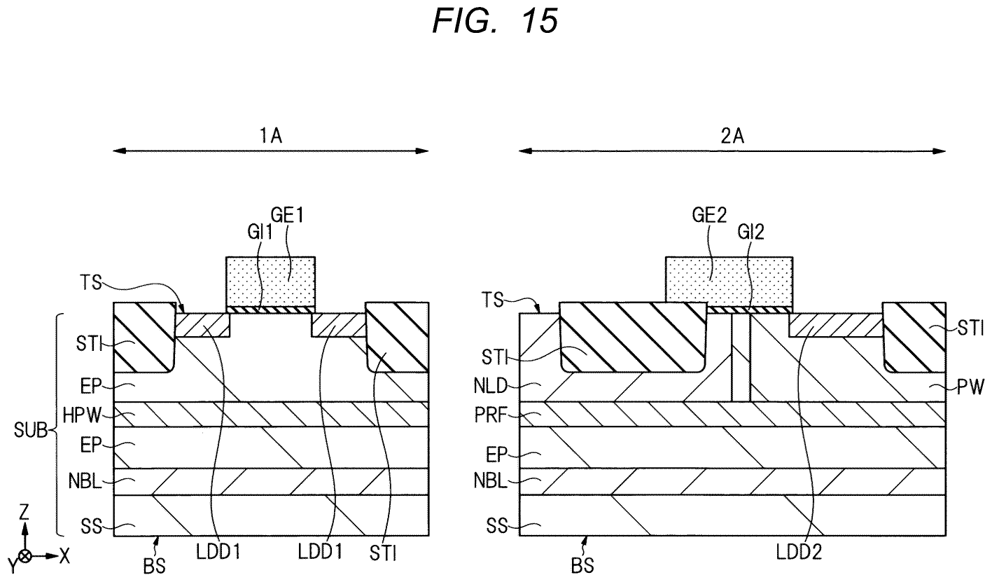

As shown in FIG. 15, by photolithography and ion implantation, the low-concentration diffusion region LDD1 is formed in the semiconductor substrate SUB in the region 1A, and the low-concentration diffusion region LDD2 is formed in the well region PW in the region 2A.

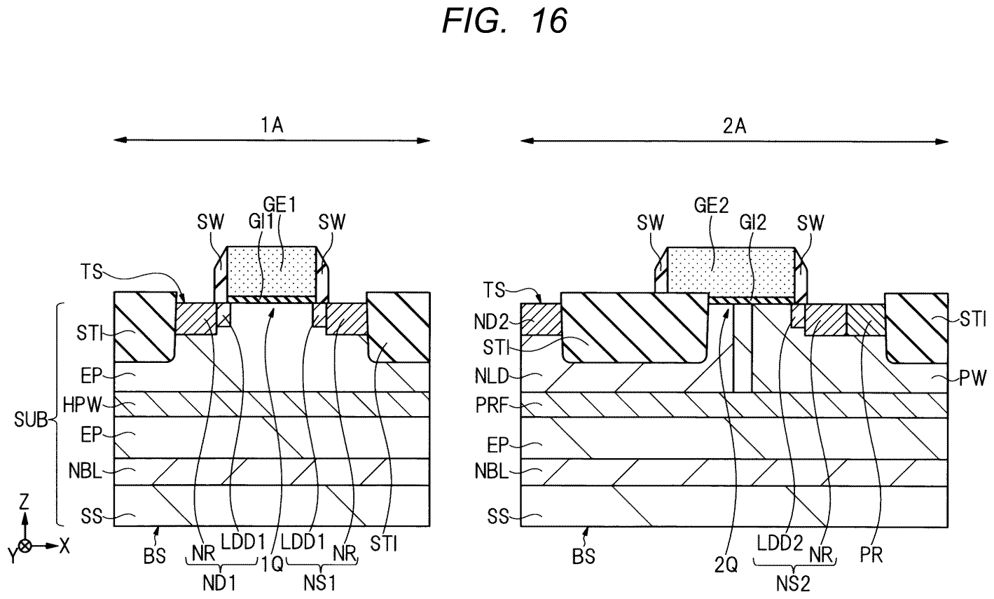

As shown in FIG. 16, the sidewall spacer SW, the high-concentration diffusion region NR, the drain region ND2, and the high-concentration diffusion region PR are formed.

First, to cover the gate electrode GE1 and the gate electrode GE2, for example, by a film-forming process using the CVD method, a laminated film including, for example, a silicon oxide film and a silicon nitride film is formed on the upper surface TS of the semiconductor substrate SUB. Next, by performing anisotropic etching on the aforementioned laminated film, the sidewall spacer SW is formed from the laminated film left on the side surface of the gate electrode GE1 and the side surface of the gate electrode GE2.

Next, using photolithography techniques and ion implantation, the high-concentration diffusion region NR is formed in the semiconductor substrate SUB in the region 1A, and the high-concentration diffusion region NR is formed in the well region PW in the region 2A, with the drain region ND2 formed in the drift region NLD. In this manner, in the region 1A, the drain region ND1 and the source region NS1, each including the low-concentration diffusion region LDD1 and the high-concentration diffusion region NR, are formed. Additionally, in the region 2A, the source region NS2, including the low-concentration diffusion region LDD2 and the high-concentration diffusion region NR, is formed. Next, using photolithography techniques and ion implantation, the high-concentration diffusion region PR is formed in the well region PW in the region 2A.

As a result, the MISFET 1Q is formed in the region 1A, and the MISFET 2Q is formed in the region 2A.

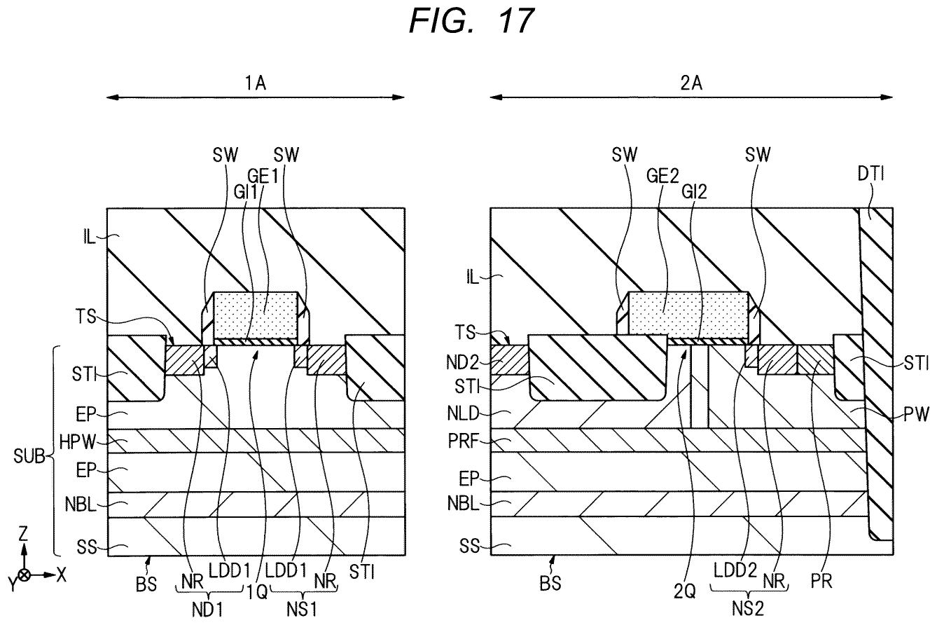

As shown in FIG. 17, the interlayer insulating film IL and the element isolation portion DTI are formed. In the first embodiment, the element isolation portion DTI is formed in the region 2A while the element isolation portion DTI is not formed in the region 1A.

First, to cover the MISFET 1Q and the MISFET 2Q, the interlayer insulating film IL is formed on the upper surface TS of the semiconductor substrate SUB and on the element isolation portion STI, for example, by a film-forming process using the CVD method. Next, a planarization process is performed on the interlayer insulating film IL using the CMP method.

Next, a resist pattern (not shown) is formed on the interlayer insulating film IL. Then, by performing anisotropic etching and isotropic etching using the resist pattern as a mask, a trench is formed in the semiconductor substrate SUB to penetrate through the interlayer insulating film IL and the element isolation portion STI and to reach a predetermined depth from the upper surface TS of the semiconductor substrate SUB.

Next, to fill the inside of the trench, an insulating film such as a silicon oxide film is formed on the interlayer insulating film IL. Then, using a polishing process with the CMP method, the insulating film located outside the trench is removed, leaving the insulating film inside the trench. In this way, the element isolation portion DTI, including the trench and the insulating film, is formed.

Subsequently, through the following manufacturing steps, the structure shown in FIG. 1 is obtained. First, using photolithography and anisotropic etching, a plurality of holes are formed in the interlayer insulating film IL. Next, the plurality of plugs PG are formed inside each of the plurality of holes.

To form the plug PG, first, a titanium film is formed inside the holes and on the interlayer insulating film IL, for example, by a film-forming process using the sputtering method. Next, a titanium nitride film is formed on the titanium film, for example, by a film-forming process using the CVD method. The titanium film and the titanium nitride film become the barrier metal film. Then, to fill the inside of the holes, a conductive film such as a tungsten film is formed on the barrier metal film, for example, by a film-forming process using the CVD method. Next, using a polishing process with the CMP method, the conductive film and the barrier metal film formed outside the holes are removed. In this way, the plug PG, including the conductive film and the barrier metal film, is formed inside the holes.

Next, a lower barrier metal film is formed on the interlayer insulating film IL. The lower barrier metal film includes, for example, a titanium film formed by the sputtering method and a titanium nitride film formed on the titanium film by the CVD method. Next, a conductive film such as an aluminum alloy film is formed on the lower barrier metal film, for example, by the sputtering method. Then, an upper barrier metal film such as a titanium nitride film is formed on the conductive film, for example, by the sputtering method. Next, by patterning the upper barrier metal film, the conductive film, and the lower barrier metal film, the plurality of wirings M1 are formed.

### Second Embodiment

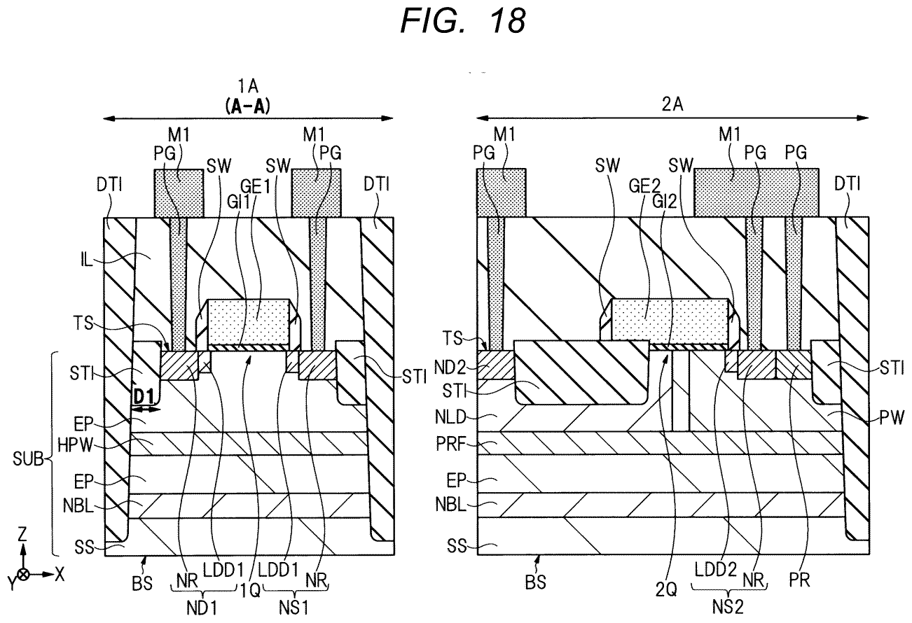

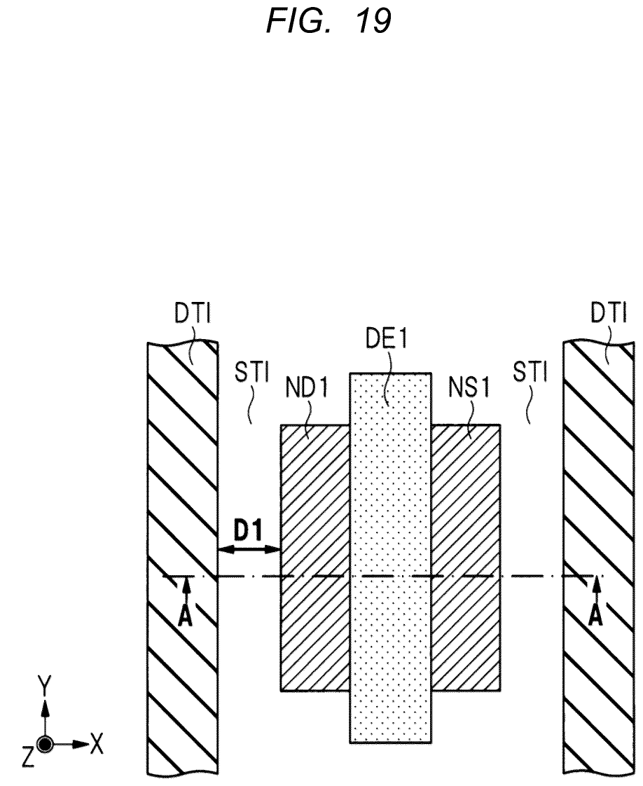

Below, the semiconductor device in the second embodiment will be described using FIGS. 18 and 19. In the following description, the differences from the first embodiment will be mainly explained, and the overlapping points with the first embodiment will be omitted. FIG. 18 shows a cross-sectional view of the MISFET 1Q along line A-A shown in FIG. 19 and a cross-sectional view of the MISFET 2Q.

As shown in FIGS. 18 and 19, in the second embodiment, the element isolation portion DTI is also formed in the region 1A. To more reliably electrically isolate the MISFET 1Q from other semiconductor elements, the element isolation portion DTI may be arranged near the MISFET 1Q in plan view. In that case, it has been revealed by the inventors of the present application that there is a risk that the side surface of the element isolation portion DTI shows n-type conductivity, causing variations in the characteristics of the MISFET 1Q.

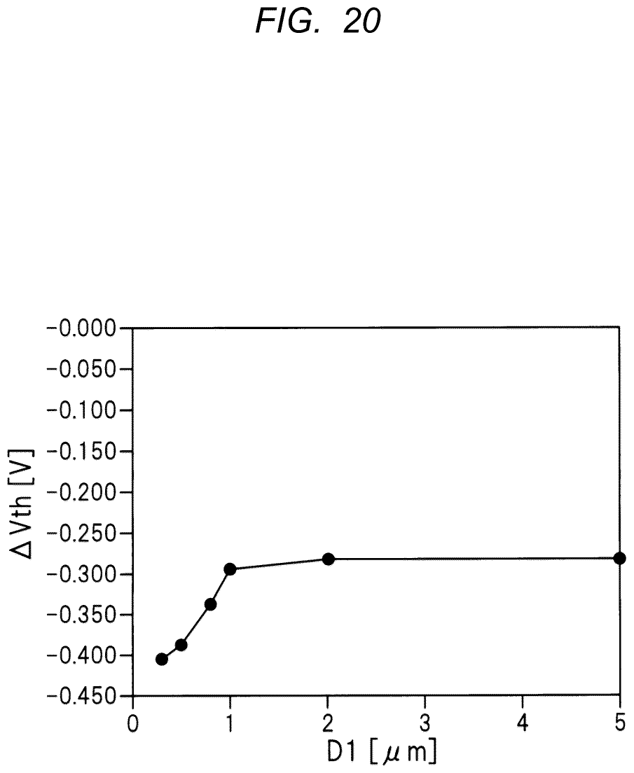

FIG. 20 shows the relationship between the distance D1 between the element isolation portion DTI and the drain region ND1 in plan view and the variation (ΔVth) of the threshold voltage of the MISFET 1Q. As shown in FIG. 20, when the distance D1 is 1 μm or less, the threshold voltage of the MISFET 1Q varies.

The reason for such variation in the threshold voltage of the MISFET 1Q is presumed to be the anisotropic etching and isotropic etching processes when forming the trench for the element isolation portion DTI. The element isolation portion DTI is formed to a position deeper than the buried region NBL and contacts the buried region NBL. It is estimated that the n-type impurities contained in the buried region NBL diffused along the trench for the element isolation portion DTI due to the etching gas used in the anisotropic etching process or the chemical solution used in the isotropic etching process. Therefore, ultimately, an n-type impurity region is formed along the side surface of the element isolation portion DTI.

To suppress the characteristic variation of the MISFET 1Q, the distance D1 should be increased. However, the larger the distance D1, the larger the planar area of the MISFET 1Q, and the larger the size of the semiconductor device. Also, the larger the distance D1, the more difficult it becomes to shrink the MISFET 1Q, making it difficult to miniaturize the semiconductor device. The impurity region HPW can resolve these issues without increasing the distance D1.

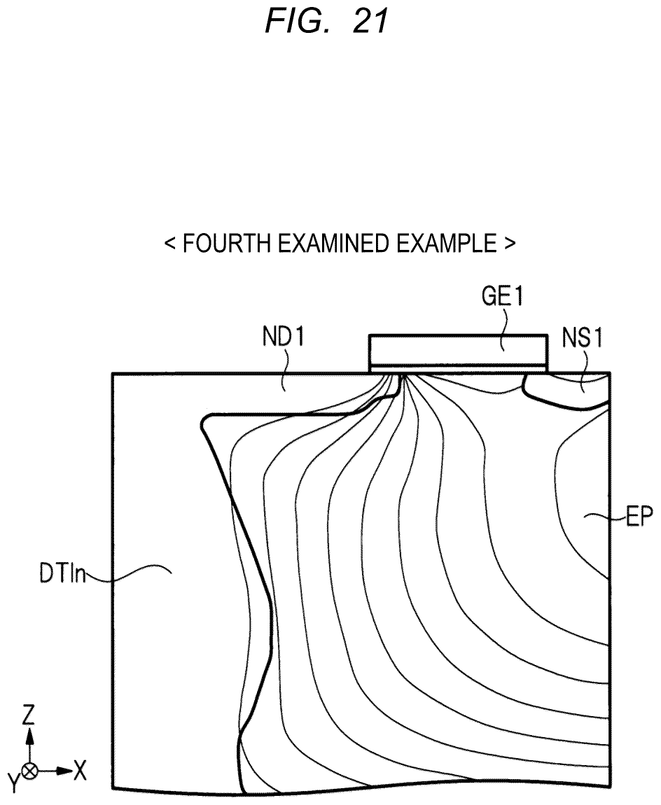

Below, the effect of the impurity region HPW in the second embodiment will be described using FIGS. 21 to 26. FIGS. 21 to 24 show the potential distribution from simulations conducted by the inventors of the present application to examine the occurrence of leakage current (Ioff characteristics) during the off operation of the MISFET 1Q. The voltages applied to the gate electrode GE1, the drain region ND1, the source region NS1, and the semiconductor layer EP are the same as in FIGS. 2 to 5.

In FIGS. 21 to 24, the locations where the element isolation portion DTI was originally formed and the n-type impurity region formed along the side surface of the element isolation portion DTI are regarded as a virtual n-type impurity region DTIn for simulation purposes.

As shown in FIG. 21, in the fourth examined example, similar to the first examined example of the first embodiment, the impurity region HPW is not formed. In the fourth examined example, equipotential lines extend not only from the drain region ND1 but also from the virtual n-type impurity region DTIn, reaching the source region NS1. That is, due to the influence of the virtual n-type impurity region DTIn, punch-through occurs more easily in the fourth examined example than in the first examined example.

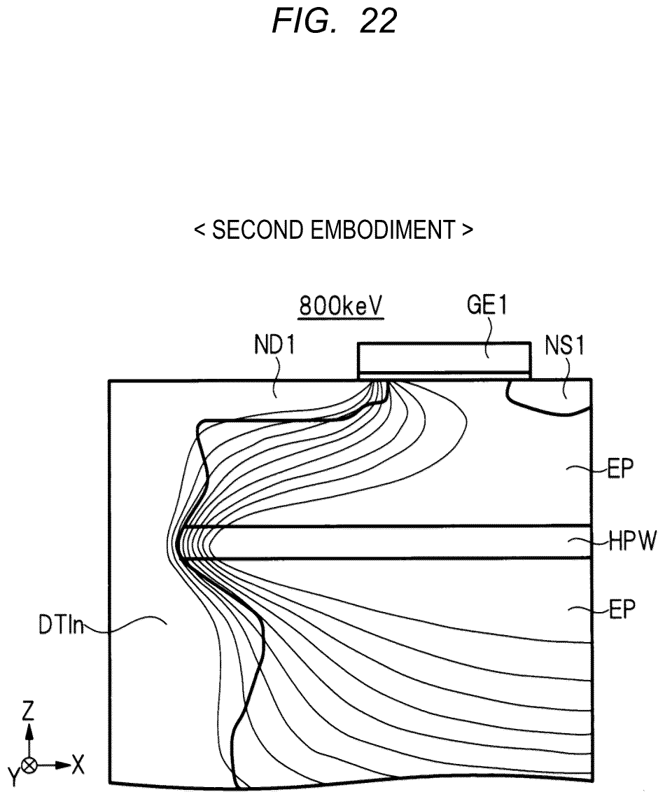

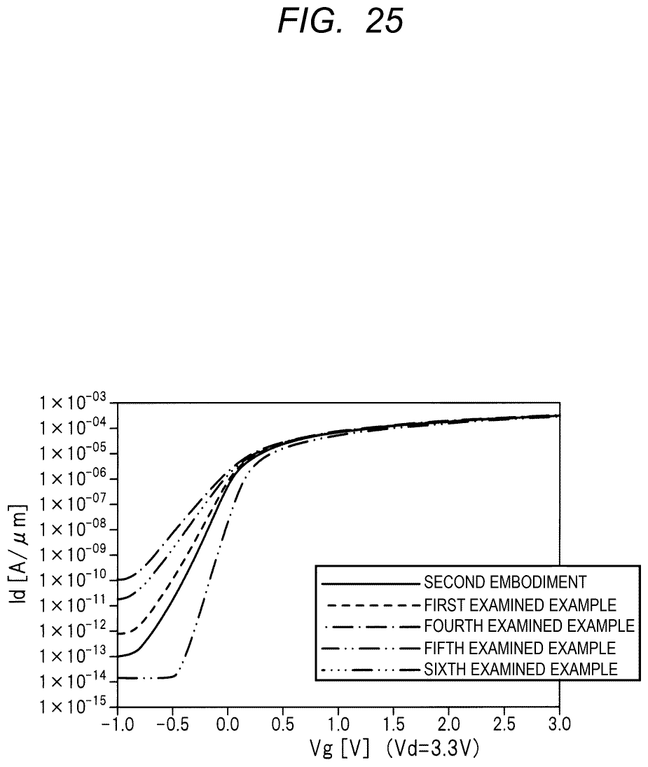

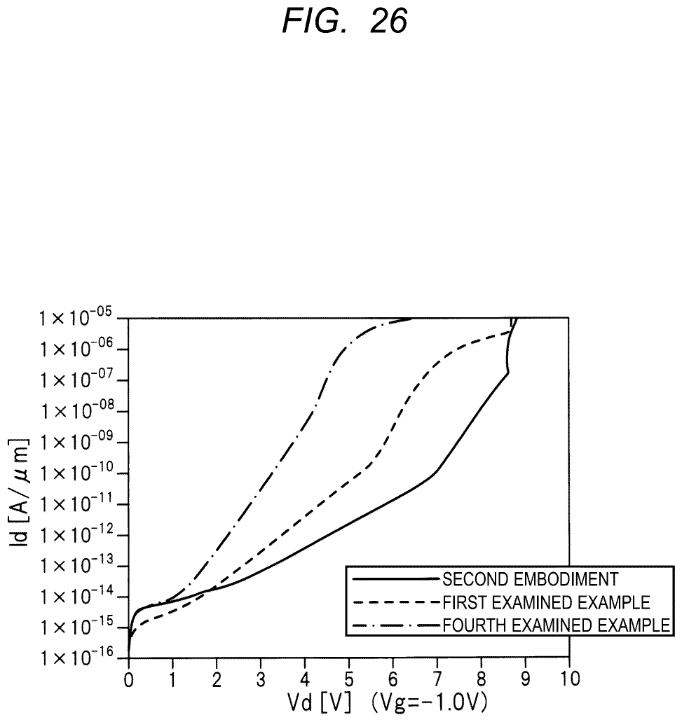

As shown in FIG. 22, in the second embodiment, the impurity region HPW is formed, so the equipotential lines do not reach the source region NS1. Therefore, as shown in FIG. 25, punch-through is less likely to occur. Also, as shown in FIG. 26, in the second embodiment, compared to the first examined example and the fourth examined example, the occurrence of leakage current during the off operation can be suppressed, and the breakdown voltage of the MISFET 1Q during the off operation can be improved. Therefore, in the second embodiment, the reliability of the semiconductor device can also be improved.

Also, in the second embodiment, even when forming the element isolation portion DTI, punch-through is less likely to occur, making it easier to shrink the MISFET 1Q. For example, even when the distance D1 is 1 μm or less, forming the impurity region HPW can suppress the occurrence of punch-through.

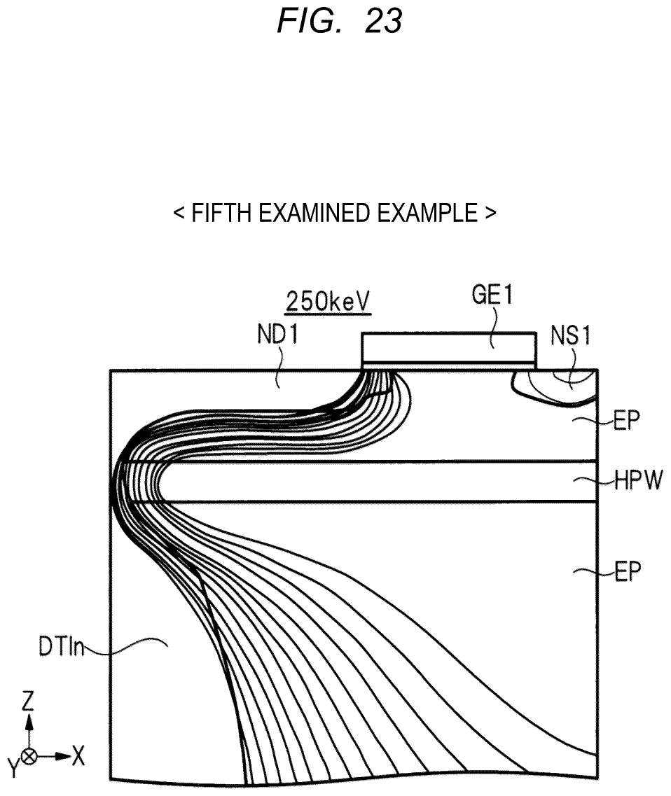

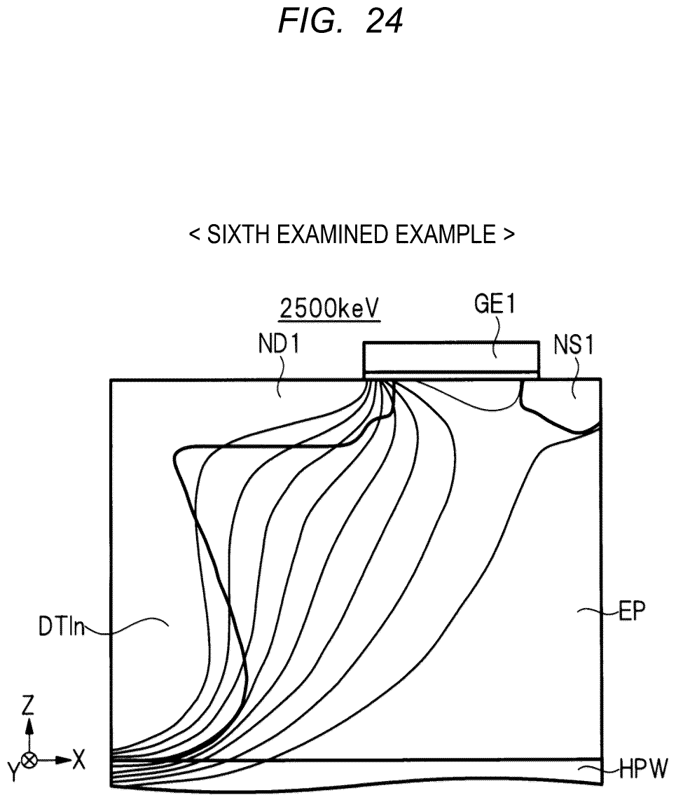

As shown in FIGS. 23 and 24, in the fifth examined example and the sixth examined example, the impurity region HPW is formed with the same implantation energy as in the second examined example and the third examined example. Therefore, in the fifth examined example, similar to the second examined example, the impurities contained in the impurity region HPW diffuse to the channel region of the MISFET 1Q. Therefore, in the fifth examined example, as shown in FIG. 25, the characteristics of the MISFET 1Q vary significantly compared to the second embodiment.

Also, in the sixth examined example, similar to the third examined example, the position of the impurity region HPW is deeper than the position of the impurity region HPW in the first embodiment, so the extension of the equipotential lines is not suppressed. Therefore, in the sixth examined example, as shown in FIG. 25, the occurrence of punch-through cannot be suppressed, and the characteristics of the sixth examined example are almost the same as those of the fourth examined example.

The position of the impurity concentration peak of the impurity region HPW is the same as the conditions described in the first embodiment using FIGS. 8 and 9.

Also, to form the element isolation portion DTI in the region 1A, in the manufacturing step of FIG. 17, the trench for the element isolation portion DTI may be formed not only in the region 2A but also in the region 1A.

Although the present invention has been specifically described based on the embodiments, the present invention is not limited to these embodiments, and various modifications can be made without departing from the gist thereof.

What is claimed is:

1. A semiconductor device comprising:
a semiconductor substrate of a first conductivity type having an upper surface;
a first source region of a second conductivity type opposite the first conductivity type, the first source region being formed in the semiconductor substrate and having a first depth from the upper surface;
a first drain region of the second conductivity type, the first drain region being formed in the semiconductor substrate and having a second depth from the upper surface; and
a first gate electrode formed via a first gate insulating film on a portion of the semiconductor substrate located between the first source region and the first drain region,
wherein a first impurity region of the first conductivity type is formed in a portion of the semiconductor substrate located under the first drain region, under the first gate electrode, and under the first source region,
wherein the first impurity region is spaced apart from the upper surface of the semiconductor substrate,
wherein an impurity concentration of the first impurity region is higher than an impurity concentration of the semiconductor substrate, and
wherein no impurity region of the first conductivity type other than the semiconductor substrate and the first impurity region is formed in a portion of the semiconductor substrate located between the first drain region, the first gate electrode, the first source region, and the first impurity region.

2. The semiconductor device according to claim 1,
wherein an impurity concentration of a portion of the semiconductor substrate located over the first impurity region is the same as an impurity concentration of a portion of the semiconductor substrate located under the first impurity region.

3. The semiconductor device according to claim 1,
wherein the semiconductor substrate comprises:
a supporting substrate of the first conductivity type; and
a semiconductor layer of the first conductivity type formed on the supporting substrate, and
wherein the first source region, the first drain region, and the first impurity region are formed in the semiconductor layer.

4. The semiconductor device according to claim 1,
wherein an impurity profile of the first impurity region has a predetermined half-width from an impurity concentration peak of the first impurity region, and
wherein the impurity concentration peak of the first impurity region is located at a position more than the half-width from the upper surface of the semiconductor substrate.

5. The semiconductor device according to claim 4,
wherein the impurity concentration peak of the first impurity region is located at a position shallower than the sum of the second depth of the first drain region and twice a length of the first gate electrode in a direction from the first drain region to the first source region from the upper surface of the semiconductor substrate.

6. The semiconductor device according to claim 1, further comprising:
a first element isolation portion formed in the semiconductor substrate and having a third depth from the upper surface,
wherein the second depth of the first drain region and the first depth of the first source region are shallower than the third depth of the first element isolation portion, and
wherein the impurity concentration peak of the first impurity region is located at a position deeper than the third depth of the first element isolation portion.

7. The semiconductor device according to claim 6,
wherein the impurity concentration peak of the first impurity region is located at a position shallower than the sum of the second depth of the first drain region and twice a length of the first gate electrode in a direction from the first drain region to the first source region from the upper surface of the semiconductor substrate.

8. The semiconductor device according to claim 7, further comprising:
a second impurity region of the second conductivity type formed in the semiconductor substrate; and
a second element isolation portion formed in the semiconductor substrate having a fourth depth from the upper surface,
wherein the second impurity region is located under the first impurity region,
wherein the fourth depth of the second element isolation portion is deeper than the third depth of the first element isolation portion, and
wherein the second element isolation portion is in contact with the first impurity region and the second impurity region.

9. The semiconductor device according to claim 8,
wherein a distance between the second element isolation portion and the first drain region in plan view is 1 μm or less.

10. The semiconductor device according to claim 1, further comprising:
a drift region of the second conductivity type formed in the semiconductor substrate;
a well region of the first conductivity type formed in the semiconductor substrate;
a second drain region of the second conductivity type formed in the drift region;
a second source region of the second conductivity type formed in the well region;
a third element isolation portion formed in the drift region to reach a predetermined depth from the upper surface of the semiconductor substrate,
a second gate insulating film formed on the drift region and on the well region,
a second gate electrode formed on the second gate insulating film and on a part of the third element isolation portion; and
a resurf region of the first conductivity type formed in a portion of the semiconductor substrate located under the drift region and the well region,
wherein a depth of the first impurity region is the same as a depth of the resurf region.

11. A method of manufacturing a semiconductor device, the method comprising:
(a) preparing a semiconductor substrate of a first conductivity type having an upper surface;
(b) forming a first impurity region of the first conductivity type in the semiconductor substrate;
(c) forming a first gate insulating film on the upper surface of the semiconductor substrate;
(d) forming a first gate electrode on the first gate insulating film; and
(e) forming a first source region of a second conductivity type opposite the first conductivity type and a first drain region of the second conductivity type in the semiconductor substrate,
wherein the first source region has a first depth from the upper surface of the semiconductor substrate,
wherein the first drain region has a second depth from the upper surface of the semiconductor substrate,
wherein the first gate electrode is formed via the first gate insulating film on a portion of the semiconductor substrate located between the first source region and the first drain region,
wherein the first impurity region is formed in a portion of the semiconductor substrate located under the first drain region, under the first gate electrode, and under the first source region,
wherein an impurity concentration of the first impurity region is higher than an impurity concentration of the semiconductor substrate,
wherein the first impurity region is spaced apart from the upper surface of the semiconductor substrate, and
wherein no impurity region of the first conductivity type other than the semiconductor substrate and the first impurity region is formed in a portion of the semiconductor substrate located between the first drain region, the first gate electrode, the first source region, and the first impurity region.

12. The method according to claim 11,
wherein an impurity concentration of a portion of the semiconductor substrate located over the first impurity region is the same as an impurity concentration of a portion of the semiconductor substrate located under the first impurity region.

13. The method according to claim 11,
wherein the semiconductor substrate comprises:
a supporting substrate of the first conductivity type; and
a semiconductor layer of the first conductivity type formed on the supporting substrate by epitaxial growth, and
wherein the first source region, the first drain region, and the first impurity region are formed in the semiconductor layer.

14. The method according to claim 11,
wherein an impurity profile of the first impurity region has a predetermined half-width from an impurity concentration peak of the first impurity region, and
wherein the impurity concentration peak of the first impurity region is located at a position more than the half-width from the upper surface of the semiconductor substrate.

15. The method according to claim 14,
wherein the impurity concentration peak of the first impurity region is located at a position shallower than the sum of the first depth of the first drain region and twice a length of the first gate electrode in a direction from the first drain region to the first source region from the upper surface of the semiconductor substrate.

16. The method according to claim 11, further comprising:
(f) forming a first element isolation portion in the semiconductor substrate,
wherein the first element isolation portion has a third depth from the upper surface of the semiconductor substrate,
wherein the first depth of the first drain region and the second depth of the first source region are shallower than the third depth of the first element isolation portion, and
wherein the impurity concentration peak of the first impurity region is located at a position deeper than the third depth of the first element isolation portion.

17. The method according to claim 16,
wherein the impurity concentration peak of the first impurity region is located at a position shallower than the sum of the first depth of the first drain region and twice a length of the first gate electrode in a direction from the first drain region to the first source region from the upper surface of the semiconductor substrate.

18. The method according to claim 17, further comprising:
(g) forming a second impurity region of the second conductivity type in the semiconductor substrate; and
(h) forming a second element isolation portion in the semiconductor substrate,
wherein the second element isolation portion has a fourth depth from the upper surface of the semiconductor substrate,
wherein the second impurity region is located under the first impurity region,
wherein the fourth depth of the second element isolation portion is deeper than the third depth of the first element isolation portion, and
wherein the second element isolation portion is in contact with the first impurity region and the second impurity region.

19. The method according to claim 18,
wherein a distance between the second element isolation portion and the first drain region in plan view is 1 μm or less.

20. The method according to claim 11, further comprising:
(i) forming a third element isolation portion in the semiconductor substrate;
(j) forming a resurf region of the first conductivity type in the semiconductor substrate;
(k) forming a drift region of the second conductivity type in the semiconductor substrate;
(l) forming a well region of the first conductivity type in the semiconductor substrate;
(m) forming a second gate insulating film on the drift region and on the well region,
(n) forming a second gate electrode on the second gate insulating film and on a part of the third element isolation portion;
(o) forming a second drain region of the second conductivity type in the drift region; and
(p) forming a second source region of the second conductivity type in the well region,
wherein the third element isolation portion is located in the drift region,
wherein the resurf region is formed in a portion of the semiconductor substrate located under the drift region and under the well region, and
wherein the (b) and the (i) are performed as the same step.
